(19) United States
(12) Patent Application Publication
(10) Pub. No.: US 2018/0291510 A1
(43) Pub. Date: Oct. 11, 2018

(54) CONTINUOUS DEPOSITION DEVICE AND METHOD OF CONTINUOUS DEPOSITION

(71) Applicant: SwiRoc Corp., Hsinchu City (TW)

(72) Inventors: WEI MIN SU, Hsinchu City (TW); PO CHIEH CHANG, Hsinchu City (TW); MING LIN CHEN, Hsinchu City (TW)

(21) Appl. No.: 15/601,557

(22) Filed: May 22, 2017

(30) Foreign Application Priority Data
Apr. 11, 2017 (TW) 106112026

(51) Int. Cl. C23C 16/54; C23C 14/56

(52) U.S. Cl. CPC C23C 16/545; C23C 14/562

(57) ABSTRACT

A continuous deposition device comprises a first fixing chamber having a first fixing unit disposed therein; a first pump coupled with the first fixing chamber to adjust the pressure in the first fixing chamber; a second fixing chamber having a second fixing unit disposed therein, wherein ends of a roll material are fix on the first fixing unit and second fixing unit respectively; a second pump coupled with the second fixing chamber to adjust the pressure in the second fixing chamber; and a plurality of reaction chambers connected with each other, wherein the upstream of the reaction chambers couples with the first fixing chamber and the downstream of the reaction chambers couples with the second fixing chamber. The roll material passes through the reaction chambers. The reaction chambers respectively provide reactants to deposit on the roll material. The present invention also provides a method of continuous deposition.

### FIELD OF THE INVENTION

The present invention relates to a deposition device and a method of deposition, particularly to a continuous deposition device and a method of continuous deposition.

### DESCRIPTION OF THE PRIOR ART

The vapor deposition process is extensively used in many fields. In a chemical vapor deposition process, one or more precursors are exposed to the surface of a substrate to enable reaction and deposition. In order to obtain high-purity products, pressure is modified in an ordinary deposition reaction to eliminate unwanted gases and avoid unnecessary reactions lest impurities be generated. Therefore, vacuuming and vacuum-breaking procedures are often undertaken repeatedly in the deposition processes of different reactants. Sometimes, several reactants are intended to be deposited on an identical substrate. The conventional technology, which undertakes the vacuuming and vacuum-breaking procedures repeatedly, would complicate the fabrication process and consume more time. Accordingly, the industry looks forward to a device that can reduce fabrication time and increase fabrication efficiency via undertaking a plurality of deposition processes continuously.

### SUMMARY OF THE INVENTION

One objective of the present invention is to provide a continuous deposition device, wherein a plurality of deposition chambers is interconnected to realize a continuous deposition process, whereby the fabrication process is exempted from the repeated vacuuming and vacuum-breaking steps that the conventional technology often uses, wherefore fabrication time is reduced and economic efficiency is increased.

In order to achieve the abovementioned objective, the present invention proposes a continuous deposition device, which comprises a first fixing chamber including a first fixing unit disposed in the first fixing chamber; a first pump connected with the first fixing chamber and used to adjust the pressure of the first fixing chamber; a second fixing chamber including a second fixing unit disposed in the second fixing chamber, wherein two ends of a roll material are respectively fixed to the first fixing unit and the second fixing unit; a second pump connected with the second fixing chamber and used to adjust the pressure of the second fixing chamber; and a plurality of reaction chambers interconnecting with each other, wherein the reaction chamber in the upstream side is connected with the first fixing chamber; the reaction chamber in the downstream side is connected with the second fixing chamber; the roll material is passed through the plurality of reaction chambers continuously; the plurality of reaction chambers respectively supplies reactants to deposit on the roll material.

The present invention also proposes a continuous deposition method, which comprises a step: providing a continuous deposition device that comprises a first fixing chamber including a first fixing unit disposed therein and a first pump used to adjust the pressure of the first fixing chamber; a second fixing chamber including a second fixing unit disposed therein and a second pump used to adjust the pressure of the second fixing chamber, wherein two ends of a roll material are respectively fixed to the first fixing unit and the second fixing unit; and a plurality of reaction chambers interconnecting with each other. The continuous deposition method further comprises steps: passing the roll material through the plurality of reaction chambers continuously; and supplying at least one reactant through the plurality of reaction chambers to deposit on the roll material.

Below, embodiments are described in cooperation with the attached drawings to make easily understood the objectives, technical contents, characteristics and accomplishments of the present invention.

### BRIEF DESCRIPTION OF THE DRAWINGS

FIG. 1 is a diagram schematically showing a continuous deposition device according to one embodiment of the present invention;

FIG. 2 is a diagram schematically showing a portion of a continuous deposition device according to another embodiment of the present invention;

FIG. 3A and FIG. 3B are diagrams schematically showing a continuous deposition device according to yet another embodiment of the present invention; and

FIG. 4 is a flowchart of a continuous deposition method according to one embodiment of the present invention.

### DESCRIPTION OF THE PREFERRED EMBODIMENT

The present invention will be described in detail with embodiments and attached drawings below. However, these embodiments are only to exemplify the present invention but not to limit the scope of the present invention. In addition to the embodiments described in the specification, the present invention also applies to other embodiments. Further, any modification, variation, or substitution, which can be easily made by the persons skilled in that art according to the embodiment of the present invention, is to be also included within the scope of the present invention, which is based on the claims stated below. Although many special details are provided herein to make the readers more fully understand the present invention, the present invention can still be practiced under a condition that these special details are partially or completely omitted. Besides, the elements or steps, which are well known by the persons skilled in the art, are not described herein lest the present invention be limited unnecessarily. Similar or identical elements are denoted with similar or identical symbols in the drawings. It should be noted: the drawings are only to depict the present invention schematically but not to show the real dimensions or quantities of the present invention. Besides, matterless details are not necessarily depicted in the drawings to achieve conciseness of the drawings.

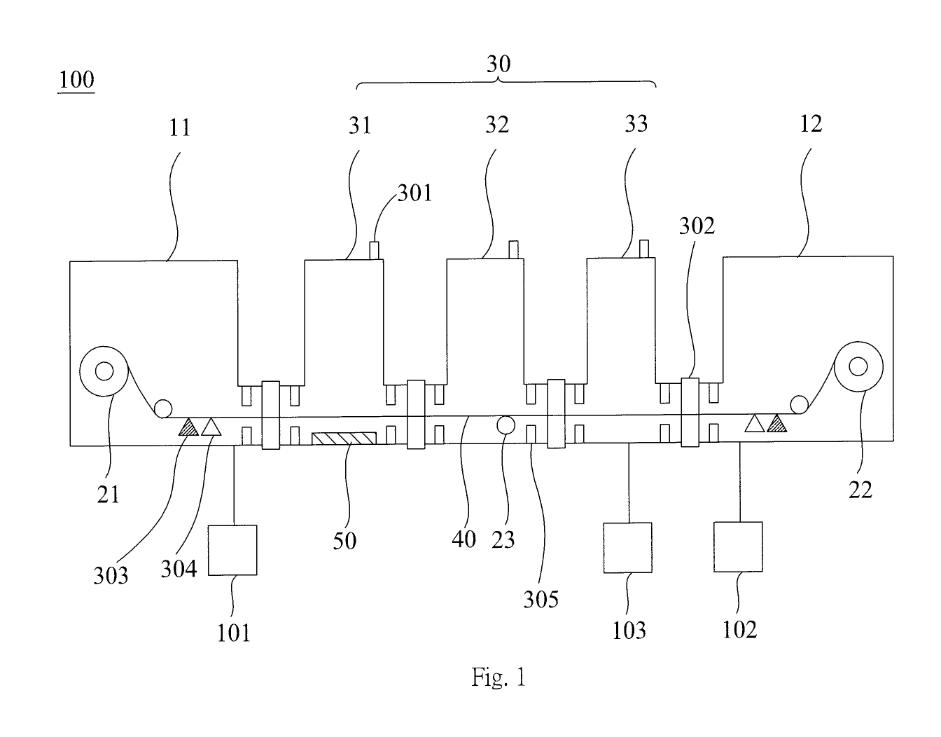

Refer to FIG. 1 a diagram schematically showing a continuous deposition device according to one embodiment of the present invention. The continuous deposition device 100 of the present invention comprises a first fixing chamber 11, a second fixing chamber 12, and a plurality of reaction chambers 30. The first fixing chamber 11 includes a first fixing unit 21 disposed therein. A first pump 101 is connected with the first fixing chamber 11 and used to adjust the pressure in the first fixing chamber 11. The second fixing chamber 12 includes a second fixing unit 22 disposed therein. A second pump 102 is connected with the second fixing chamber 12 and used to adjust the pressure in the second fixing chamber 12. Two ends of a roll material 40 are respectively fixed to the first fixing unit 21 and the second fixing unit 22. In one embodiment, the continuous deposition device 100 further comprises at least one third fixing unit 23 respectively disposed in different reaction chambers 31, 32 and 33 and used to support the roll material 40 passing through the reaction chambers. In the drawings of the specification, the third fixing unit 23 is depicted to be a roller for exemplification. However, the present invention is not limited by these drawings. The third fixing unit 23 may be any shape or element able to support the roll material.

The reaction chambers 30 interconnect mutually. The upstream reaction chamber 30 may be connected with the first fixing chamber 11, and the downstream reaction chamber 30 may be connected with the second fixing chamber 12, whereby the roll material 40 can pass through the plurality of reaction chambers 30 continuously. The plurality of reaction chambers 30 is used to respectively provide reactants (not shown in the drawings) to the roll material 40. In some embodiments, chemical vapor deposition reactions or physical vapor deposition reactions can be undertaken in the plurality of reaction chambers. In the drawings, three reaction chambers are used to exemplify the plurality of reaction chambers. However, the number of the reaction chambers of the present invention is not limited by the drawings. The number of the reaction chambers can be increased or decreased according to the requirement of the fabrication process, which will be explained in detail thereinafter.

The roll material is a strip-like material made of a material selected from a group including natural fibers, artificial fibers, non-woven fabrics, filter nets, synthetic leathers, natural leathers, polyethylene terephthalate (PET), thermoplastic polyurethane (TPU), polyvinyl chloride (PVC), polypropylene (PP), and polytetrafluoroethylene (PTFE). The strip-like material can be passed from the first fixing chamber through the reaction chambers to the second fixing chamber continuously. In some embodiments, the roll material is passed by rails or rollers continuously. It should be mentioned particularly: the reaction chambers of the continuous deposition device of the present invention are not enclosed independently but are interconnected mutually. Therefore, deposition reactions of the strip-like material can be undertaken continuously.

In one embodiment, at least one of the plurality of reaction chambers 30 includes a temperature adjusting unit 50 that can adjust the temperature of the roll material 40 while the roll material 40 continuously passes through the reaction chambers 30. For example, the temperature adjusting unit 50 is a heater or cooler to increase or decrease the temperature of the roll material 40.

In the present invention, the reactants provided by the plurality of reaction chambers 30 may be different. For example, while different reactants are intended to be deposited on the roll material, the reaction chamber 31 provides a first reactant on the roll material; the reaction chamber 32 provides a second reactant on the roll material; the reaction chamber 33 provides a third reactant on the roll material. In some embodiments, a part of the reactants provided by the plurality of reaction chambers 30 are identical. For example, the reaction chamber 31 provides a first reactant on the roll material; the reaction chamber 32 provides a second reactant on the roll material; the reaction chamber 33 also provides the first reactant on the roll material. Therefore, the types of reactants can be adjusted according to requirement.

While adjacent reaction chambers provide different reactants, at least one of the plurality of reaction chambers has an exhaust vent 301, which is disposed in the outlet side of the reaction chamber and used to exhaust the reactant not disposed on the roll material lest cross contamination affect the succeeding process. While different reactants are to be deposited on the roll material, the reaction conditions may be different. In order to use different reaction conditions for different reactants, the continuous deposition device of the present invention further comprises a third pump 103, which is connected with at least one of the plurality of reaction chambers and used to adjust the pressure in at least one of the reaction chambers. Therefore, the pressures of the plurality of reaction chambers may be identical, different, or partly identical.

In some embodiments, the reaction chambers 30 further include connection members 302, which enable each of the reaction chambers 30 to be detachably coupled to the first fixing chamber, the second fixing chamber or another reaction chamber. The connection members 302 enable the quantity of the reaction chambers to be adjusted in a modularized way. Therefore, the number of the reaction chambers can be conveniently increased or decreased according to requirement.

In some embodiments, the first fixing chamber 11 and the second fixing chamber 12 respectively include alignment units 303, which can align two ends of the roll material 40. For example, the alignment unit 303 includes an electric eye. In some embodiments, the first fixing chamber 11 and the second fixing chamber 12 respectively include tension control units 304, which can control the tension of the roll material 40.

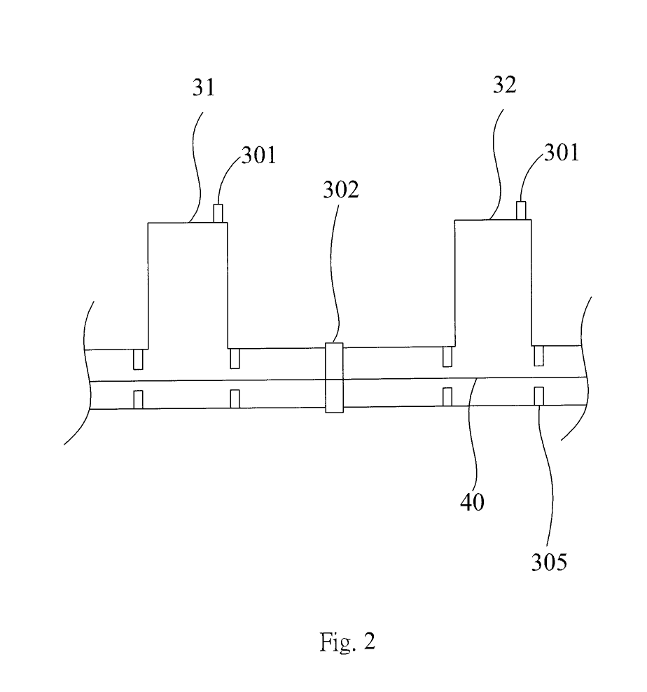

In some embodiments, the continuous deposition device further comprises at least one gate 305, which is disposed between the first fixing chamber 11 and the reaction chamber 31, or between the second fixing chamber 12 and the reaction chamber 33, or between the adjacent reaction chambers of the reaction chambers 31, 32 and 33, wherein the roll material 40 is continuously passed through the plurality of reaction chambers 31, 32 and 33 via at least one gate 305. It should be noted: the gate 305 is not closed completely but has a gap to allow the roll material 40 to pass. The gate 305 can prevent from the cross contamination of the reactants of different reaction chambers. The distance between two adjacent gates 305, which are connected with the first fixing chamber 11 and the reaction chamber 31, or connected with the second fixing chamber 12 and the reaction chamber 33, or connected with the adjacent reaction chambers of the reaction chambers 31, 32 and 33, can be adjusted according to requirement. As shown in FIG. 2, the gates 305 can function as a buffer preventing the reactants from contaminating each other.

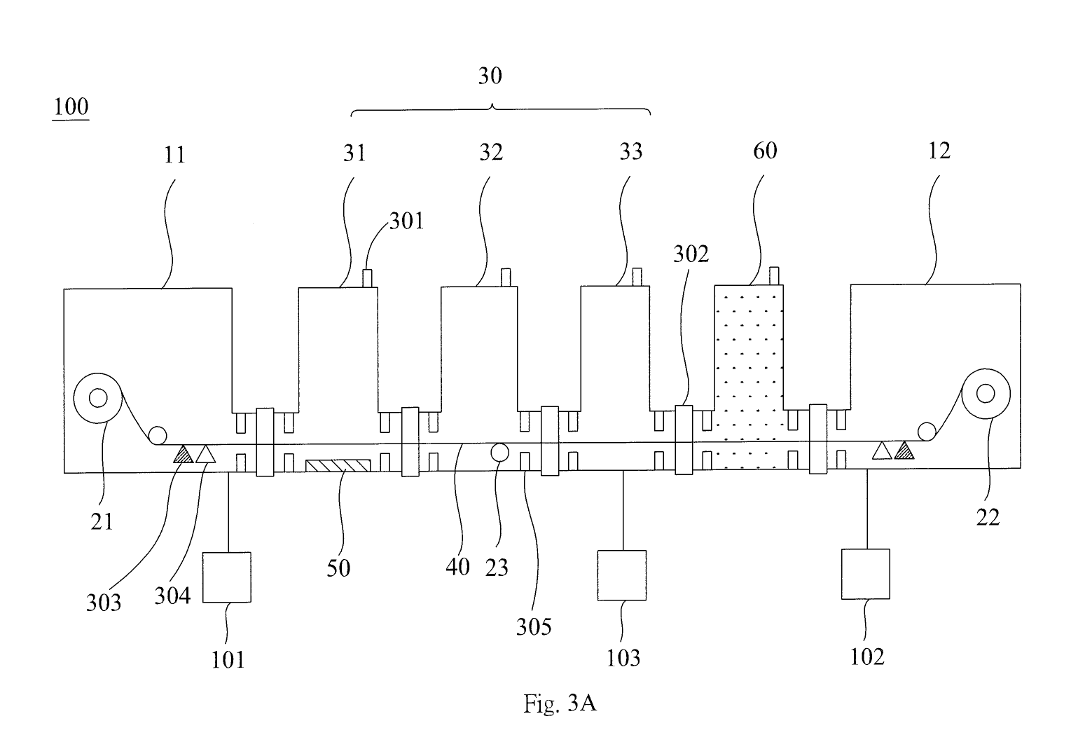

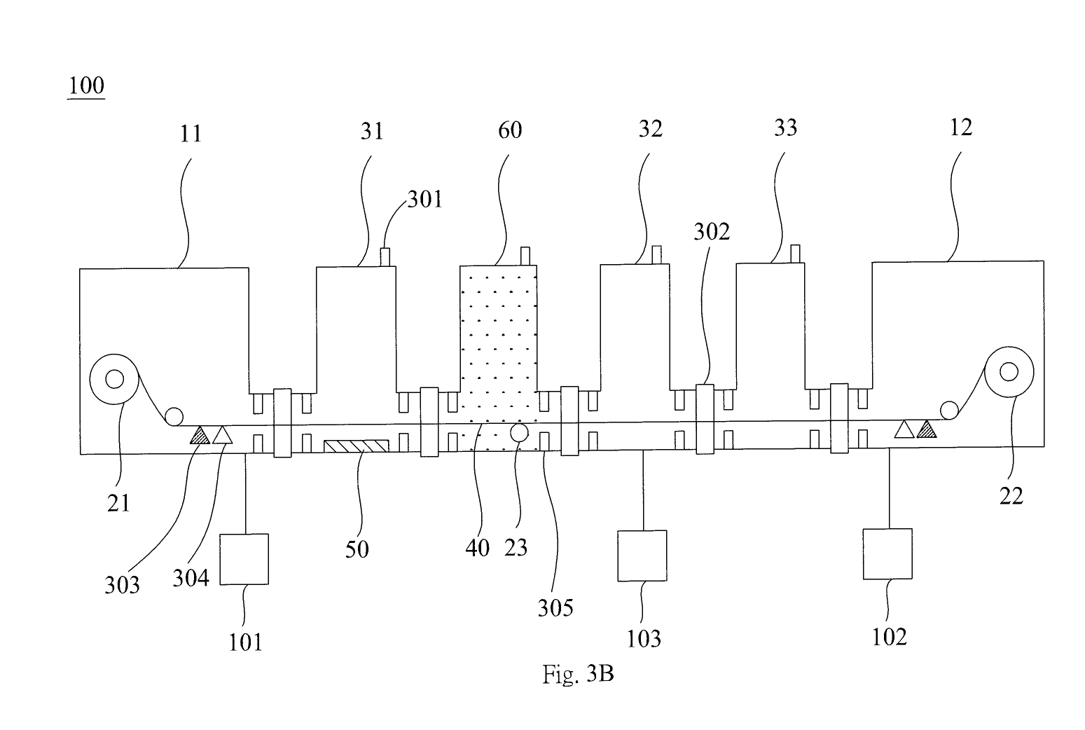

In one embodiment, the continuous deposition device 100 further comprises at least one buffer chamber 60, as shown in FIG. 3A and FIG. 3B. The buffer chamber 60 are disposed in each reaction chamber or between any two reaction chambers. Alternatively, the buffer chamber 60 is disposed between the reaction chamber and the second fixing chamber 12. The buffer chamber 60 is used to prevent from cross contamination of reactants or assist in cooling. The buffer chamber 60 also includes connection members 302. The connection members 302 enable the buffer chamber 60 to be detachably coupled to the reaction chambers or the second fixing chamber 12.

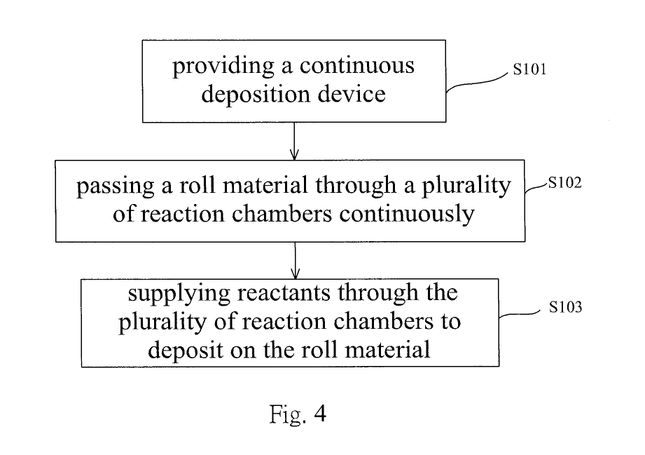

Below is described the continuous deposition method of the present invention. Refer to FIG. 4. The continuous deposition method of the present invention comprises Step S101, Step S102, and Step S103. In Step S101, provide a continuous deposition device. The continuous deposition device comprises a first fixing chamber, a second fixing chamber, and a plurality of reaction chambers. The detail of the continuous deposition device has been described above and will not repeat herein. Next, in Step S102, pass a roll material through the plurality of reaction chambers continuously. The roll material is a strip-like material made of a material selected from a group including natural fibers, artificial fibers, non-woven fabrics, filter nets, synthetic leathers, natural leathers, polyethylene terephthalate (PET), thermoplastic polyurethane (TPU), polyvinyl chloride (PVC), polypropylene (PP), and polytetrafluoroethylene (PTFE). The strip-like material can be passed from the first fixing chamber through the reaction chambers to the second fixing chamber continuously. In some embodiments, the roll material is passed by rails or rollers continuously. In some embodiments, the continuous deposition device further comprises at least one gate, which is disposed between the first fixing chamber and the reaction chamber, or between the second fixing chamber and the reaction chamber, or between the adjacent reaction chambers. The roll material is continuously passed through the plurality of reaction chambers via at least one gate. While the roll material is passed through the gate, the gate is not closed completely but has a gap to allow the roll material to pass. Thereby, the gates can prevent the reactants from contaminating each other.

Then, in Step S103, the plurality of reaction chambers provides reactants to the roll material. Chemical vapor deposition reactions or physical vapor deposition reactions are undertaken in the reaction chambers. The reactants provided by the reaction chambers may be identical, different, or partly identical. Step S103 may further include a step: using at least one third pump, which is connected with at least one reaction chamber, to adjust the pressure of at least one reaction chamber. Thereby, the pressures of the reaction chambers may be identical, different, or partly identical.

In conclusion, the present invention proposes a continuous deposition device and a continuous deposition method, which can undertake a continuous deposition process of a plurality of reactants on a strip-like material, wherein the pumps that are respectively connected with the chambers can adjust the pressures of the chambers, whereby the present invention can realize continuous deposition of a plurality of reactants without using vacuuming/vacuum-breaking steps, wherefore the present invention can decrease the fabrication time, simplify the fabrication process, and increase the economic efficiency. Besides, the present invention can arbitrarily increase or decrease the quantity of the chambers in a modularized way according to requirement and thus enhance the flexibility of the fabrication process.

What is claimed is:

1. A continuous deposition device comprising
a first fixing chamber including a first fixing unit disposed in the first fixing chamber;
a first pump connected with the first fixing chamber and used to adjust pressure of the first fixing chamber;
a second fixing chamber including a second fixing unit disposed in the second fixing chamber, wherein two ends of a roll material are respectively fixed to the first fixing unit and the second fixing unit;
a second pump connected with the second fixing chamber and used to adjust pressure of the second fixing chamber; and
a plurality of reaction chambers interconnecting with each other, wherein the reaction chamber in an upstream side is connected with the first fixing chamber; the reaction chamber in a downstream side is connected with the second fixing chamber; the roll material is passed through the plurality of reaction chambers continuously; the plurality of reaction chambers respectively supplies reactants to deposit on the roll material.

2. The continuous deposition device according to claim 1, wherein at least one of the plurality of reaction chambers includes a temperature adjusting unit used to adjust temperature of the roll material.

3. The continuous deposition device according to claim 1 further comprising
at least one third pump connected with at least one of the plurality of reaction chambers and used to adjust pressure of at least one of the plurality of reaction chambers.

4. The continuous deposition device according to claim 1, wherein at least one of the plurality of reaction chambers includes an exhaust vent disposed in an outlet side of the reaction chamber.

5. The continuous deposition device according to claim 1 further comprising
a buffer chamber disposed among the plurality of reaction chambers or disposed between the second fixing chamber and the reaction chamber in a downstream side.

6. The continuous deposition device according to claim 1, wherein the reaction chamber includes a connection member that enables the reaction chamber to be detachably connected with the first fixing chamber, the second fixing chamber or one of the reaction chambers.

7. The continuous deposition device according to claim 1, wherein the reactants provided by the plurality of reaction chambers are different or partly identical.

8. The continuous deposition device according to claim 1, wherein chemical vapor deposition or physical vapor deposition is undertaken in the plurality of reaction chambers.

9. The continuous deposition device according to claim 1, wherein the roll material is a strip-like material made of a material selected from a group including natural fibers, artificial fibers, non-woven fabrics, filter nets, synthetic leathers, natural leathers, polyethylene terephthalate (PET), thermoplastic polyurethane (TPU), polyvinyl chloride (PVC), polypropylene (PP), and polytetrafluoroethylene (PTFE).

10. The continuous deposition device according to claim 1, wherein pressures of the plurality of reaction chambers are different or partly identical.

11. The continuous deposition device according to claim 1, wherein the first fixing chamber and the second fixing chamber respectively include alignment units used to align two ends of the roll material.

12. The continuous deposition device according to claim 1, wherein the first fixing chamber and the second fixing chamber respectively include tension control units used to control tension of the roll material.

13. The continuous deposition device according to claim 1 further comprising at least one gate, which is disposed between the first fixing chamber and the reaction chamber, or between the second fixing chamber and the reaction chamber, or between the adjacent reaction chambers, wherein the roll material is continuously passed through the plurality of reaction chambers via at least one gate.

14. A continuous deposition method comprising the following steps:
providing a continuous deposition device, which comprises:
a first fixing chamber including a first fixing unit disposed in the first fixing chamber and a first pump used to adjust pressure of the first fixing chamber;
a second fixing chamber including a second fixing unit disposed in the second fixing chamber and a second pump used to adjust pressure of the second fixing chamber, wherein two ends of a roll material are respectively fixed to the first fixing unit and the second fixing unit; and
a plurality of reaction chambers interconnecting with each other, wherein the reaction chamber in an upstream side is connected with the first fixing chamber, and the reaction chamber in a downstream side is connected with the second fixing chamber;
passing the roll material through the plurality of reaction chambers continuously; and
supplying at least one reactant through the plurality of reaction chambers to deposit on the roll material.

15. The continuous deposition method according to claim 14 further comprising a step:
using a third pump to adjust pressure of at least one of the plurality reaction chambers, wherein the third pump is connected with at least one of the plurality of reaction chambers.

16. The continuous deposition method according to claim 14, wherein in the step of supplying at least one reactant to deposit on the roll material, the reactants supplied by the plurality of reaction chambers are different or partly identical.

17. The continuous deposition method according to claim 14, wherein in the step of supplying at least one reactant to deposit on the roll material, pressures of the plurality of reaction chambers are different or partly identical.

18. The continuous deposition method according to claim 14, wherein chemical vapor deposition or physical vapor deposition is undertaken in the plurality of reaction chambers.

19. The continuous deposition method according to claim 14, wherein the continuous deposition device further comprises at least one gate, which is disposed between the first fixing chamber and the reaction chamber, or between the second fixing chamber and the reaction chamber, or between the adjacent reaction chambers, and wherein the roll material is continuously passed through the plurality of reaction chambers via at least one gate.

20. The continuous deposition method according to claim 19, wherein while the roll material is passed through the gate, the gate is not completely closed.
